(19) United States
(12) Patent Application Publication
(10) Pub. No.: US 2011/0101317 A1
(43) Pub. Date: May 5, 2011

(54) Electronic Devices and Methods of Making Them Using Solution Processing Techniques

(75) Inventors: John James Gregory, Cambridgeshire (GB); Barry Wild, Cambridgeshire (GB); Hidehiro Yoshida, Osaka (JP); Kenji Okumoto, Osaka (JP)

(73) Assignee: Cambridge Display Technology Limited, Cambridgeshire (GB)

(21) Appl. No.: 12/922,416

(22) PCT Filed: Mar. 13, 2009
(86) PCT No.: PCT/EP09/52974

§ 371 Date: Dec. 20, 2010

(30) Foreign Application Priority Data
Mar. 14, 2008 (GB) 0804875.3

(51) Int. Cl. H01L 51/10; H01L 51/40

(52) U.S. Cl. 257/40; 438/99; 257/E51.002; 257/E51.001

(57) ABSTRACT

A method of manufacturing an electronic device comprises: providing a base comprising circuit elements; forming a double bank well-defining structure over the base, comprising a first layer of insulating material and a second layer of insulating material thereover; and depositing a solution of organic material in the well defined by the double bank structure. The double bank well-defining structure is formed by removing material from the first and second layers in a single processing step to form the well. The first layer is made of a material which is removed at a faster rate than material of the second layer to form an overhanging step structure in which the second layer protrudes out over an edge of the first layer.

### FIELD OF INVENTION

The present invention relates to electronic devices and methods of making them using solution processing techniques. Particular embodiments of the present invention relate to organic thin film transistors, organic optoelectronic devices, organic light emissive display devices and methods of making the devices using solution processing techniques.

### BACKGROUND OF THE INVENTION

Methods of manufacturing electronic devices involving depositing active components from solution are known in the art. Such methods involve the preparation of a substrate onto which one or more active components can be deposited. If active components are deposited from solution, one problem is how to contain the active components in desired areas of the substrate. One solution to this problem is to provide a substrate comprising a patterned bank layer defining wells in which the active components can be deposited in solution. The wells contain the solution whilst it is drying, such that the active components remain in the areas of the substrate defined by the wells.

Such solution processing methods have been found to be particularly useful for deposition of organic materials in solution. The organic materials may be conductive, semi-conductive, and/or opto-electrically active such that they can emit light when an electric current is passed through them or detect light by generating a current when light impinges on them. Devices which utilize these materials are known as organic electronic devices. An example is an organic transistor device. If the organic material is a light-emissive material the device is known as an organic light-emissive device. Transistors and light emissive devices are discussed in more detail below.

Transistors can be divided into two main types: bipolar junction transistors and field-effect transistors. Both types share a common structure comprising three electrodes with a semi-conductive material disposed between them in a channel region. The three electrodes of a bipolar junction transistor are known as the emitter, collector and base, whereas in a field-effect transistor the three electrodes are known as the source, drain and gate. Bipolar junction transistors may be described as current-operated devices as the current between the emitter and collector is controlled by the current flowing between the base and emitter. In contrast, field-effect transistors may be described as voltage-operated devices as the current flowing between source and drain is controlled by the voltage between the gate and the source.

Transistors can also be classified as p-type and n-type according to whether they comprise semi-conductive material which conducts positive charge carriers (holes) or negative charge carriers (electrons) respectively. The semi-conductive material may be selected according to its ability to accept, conduct, and donate charge. The ability of the semi-conductive material to accept, conduct, and donate holes or electrons can be enhanced by doping the material. The material used for the source and drain electrodes can also be selected according to its ability to accept and injecting holes or electrodes.

For example, a p-type transistor device can be formed by selecting a semi-conductive material which is efficient at accepting, conducting, and donating holes, and selecting a material for the source and drain electrodes which is efficient at injecting and accepting holes from the semi-conductive material. Good energy-level matching of the Fermi-level in the electrodes with the HOMO level of the semi-conductive material can enhance hole injection and acceptance. In contrast, an n-type transistor device can be formed by selecting a semi-conductive material which is efficient at accepting, conducting, and donating electrons, and selecting a material for the source and drain electrodes which is efficient at injecting electrons into, and accepting electrons from, the semi-conductive material. Good energy-level matching of the Fermi-level in the electrodes with the LUMO level of the semi-conductive material can enhance electron injection and acceptance. Ambipolar devices that can function as n-type or p-type devices are also known.

Transistors can be formed by depositing the components in thin films to form a thin film transistor (TFT). When an organic material is used as the semi-conductive material in such a device, it is known as an organic thin film transistor (OTFT).

Various arrangements for organic thin film transistors are known. One such device is an insulated gate field-effect transistor which comprises source and drain electrodes with a semi-conductive material disposed therebetween in a channel region, a gate electrode disposed adjacent the semi-conductive material and a layer of insulting material disposed between the gate electrode and the semi-conductive material in the channel region.

OTFTs may be manufactured by low cost, low temperature methods such as solution processing. Moreover, OTFTs are compatible with flexible plastic substrates, offering the prospect of large-scale manufacture of OTFTs on flexible substrates in a roll-to-roll process.

An example of such an organic thin film transistor is shown in FIG. 1. The illustrated structure may be deposited on a substrate 1 and comprises source and drain electrodes 2, 4 which are spaced apart with a channel region 6 located between them. An organic semiconductor (OSC) 8 is deposited in the channel region 6 and may extend over at least a portion of the source and drain electrodes 2, 4. An insulating layer 10 of dielectric material is deposited over the organic semi-conductor 8 and may extend over at least a portion of the source and drain electrodes 2, 4. Finally, a gate electrode 12 is deposited over the insulating layer 10. The gate electrode 12 is located over the channel region 6 and may extend over at least a portion of the source and drain electrodes 2, 4.

The structure described above is known as a top-gate organic thin film transistor as the gate is located on a top side of the device. Alternatively, it is also known to provide the gate on a bottom side of the device to form a so-called bottom-gate organic thin film transistor.

An example of such a bottom-gate organic thin film transistor is shown in FIG. 2. In order to more clearly show the relationship between the structures illustrated in FIGS. 1 and 2, like reference numerals have been used for corresponding parts. The bottom-gate structure illustrated in FIG. 2 comprises a gate electrode 12 deposited on a substrate 1 with an insulating layer 10 of dielectric material deposited thereover. Source and drain electrodes 2, 4 are deposited over the insulating layer 10 of dielectric material. The source and drain electrodes 2, 4 are spaced apart with a channel region 6 located therebetween over the gate electrode. An organic semiconductor (OSC) 8 is deposited in the channel region 6 and may extend over at least a portion of the source and drain electrodes 2, 4.

One problem with the aforementioned arrangements is how to contain the OSC within the channel region when it is deposited. A solution to this problem is to provide a patterned layer of insulating bank material 14 defining a well in which the OSC 8 can be deposited from solution by, for example, inkjet printing. Such an arrangement is shown in FIGS. 3 and 4 for bottom and top gate organic thin film transistors respectively. Again, in order to more clearly show the relationship between the structures illustrated in FIGS. 1 and 2, with those illustrated in FIGS. 3 and 4, like reference numerals have been used for corresponding parts.

The periphery of the well defined by the patterned layer of insulating material 14 surrounds some or all of the channel 6 defined between the source and drain electrodes 2, 4 in order to facilitate deposition of the OSC 8 by, for example, inkjet printing. Furthermore, as the insulating layer 14 is deposited prior to deposition of the OSC 8, it may be deposited and patterned without damaging the OSC. The structure of the insulating layer 14 can be formed in a reproducible manner using known deposition and patterning techniques such as photolithography of positive or negative resists, wet etching, dry etching, etc.

Even if a patterned layer of well-defining bank material is provided, problems still exist in containing the OSC within the channel region and providing good film formation of the OSC in the channel region using solution processing techniques for deposition of the OSC. Uncontrollable wetting of the well-defining bank layer may occur since the contact angle of the OSC solution on the well-defining bank layer is typically low. In the worst case the OSC may overspill the wells.

One solution is to treat the surface of the well-defining bank using, for example, a fluorine based plasma such as CF₄ in order to reduce its wettability prior to depositing the OSC from solution. A de-wetting surface on the top of the well-defining bank layer aids in containing the OSC within the wells when it is deposited.

Another solution is to use an inherently low-wetting material for the well-defining bank layer. US 2007/0023837 describes an arrangement in which a low-wetting fluorine containing polymer such as “Cytop” made by Asahi Glass in Japan is used to form a patterned well-defining bank layer when manufacturing a TFT substrate. The low-wetting fluorine containing polymer material is good at preventing the OSC from over-spilling the wells when deposited from solution. However, as the sides of the well are also low-wetting, the solution tends to be contained on the base of the well leading to poor film formation. That is, because the solution of OSC doesn't wet the sides of the well it forms a curved drop on the base of the well and dries to form a film of uneven thickness. Films of uneven thickness can adversely effect the performance of a resultant device as is known in the art.

US 2007/0020899 discloses treating the surface of a bank layer defining a wiring pattern for an electronic substrate using a fluorine based plasma in order to reduce its wettability as discussed previously. This document also describes an alternative method in which a two-layer bank structure is provided which defines a wiring pattern for an electronic substrate. The two-layer bank structure comprises a first layer which has good wettability and a second layer thereover comprising a low-wetting fluorine containing polymer.

With the aforementioned two-layer bank structure, a liquid deposited in the wells can wet the sides of the wells made of the first layer to provide good film formation in the wells on drying whereas the second layer prevents the liquid from over-spilling the wells. The document suggests that the materials for both the first and second bank layers should be polymers including siloxane bonds in a main chain and the polymer of the second bank layer should include fluorine bonds in a side chain. Materials for the second bank layer are described as having contact angles of 50° and above. A manufacturing process is also disclosed in which the two layer bank structure is formed, active component is deposited in wells defined by the bank structure, and then the active component and the bank structure are baked at the same time.

The aforementioned prior art relates to the provision of low-wettability banks for the manufacture of TFT substrates although the use of single bank layer structures for light emissive materials is also mentioned. Organic light emissive devices are discussed in more detail below.

Displays fabricated using OLEDs (organic light emitting devices) provide a number of advantages over other flat panel technologies. They are bright, colourful, fast-switching, provide a wide viewing angle, and are easy and cheap to fabricate on a variety of substrates. Organic (which here includes organometallic) light emitting diodes (LEDs) may be fabricated using materials including polymers, small molecules and dendrimers, in a range of colours which depend upon the materials employed. Examples of polymer-based organic LEDs are described in WO 90/13148, WO 95/06400 and WO 99/48160. Examples of dendrimer-based materials are described in WO 99/21935 and WO 02/067343. Examples of so called small molecule based devices are described in U.S. Pat. No. 4,539,507.

A typical OLED device comprises two layers of organic material, one of which is a layer of light emitting material such as a light emitting polymer (LEP), oligomer or a light emitting low molecular weight material, and the other of which is a layer of a hole transporting material such as a polythiophene derivative or a polyaniline derivative.

OLEDs may be deposited on a substrate in a matrix of pixels to form a single or multi-colour pixellated display. A multicoloured display may be constructed using groups of red, green, and blue emitting pixels. So-called active matrix displays have a memory element, typically a storage capacitor and a thin film transistor (TFT), associated with each pixel whilst passive matrix displays have no such memory element and instead are repetitively scanned to give the impression of a steady image. Other passive displays include segmented displays in which a plurality of segments share a common electrode and a segment may be lit up by applying a voltage to its other electrode. A simple segmented display need not be scanned but in a display comprising a plurality of segmented regions the electrodes may be multiplexed (to reduce their number) and then scanned.

FIG. 5 shows a vertical cross section through an example of an OLED device 100. In an active matrix display, part of the area of a pixel is occupied by associated drive circuitry (not shown in FIG. 5). The structure of the device is somewhat simplified for the purposes of illustration.

The OLED 100 comprises a substrate 102, typically 0.7 mm or 1.1 mm glass but optionally clear plastic or some other substantially transparent material. An anode layer 104 is deposited on the substrate, typically comprising around 40 to 150 nm thickness of ITO (indium tin oxide), over part of which is provided a metal contact layer. Typically the contact layer comprises around 500 nm of aluminium, or a layer of aluminium sandwiched between layers of chrome, and this is sometimes referred to as anode metal. Glass substrates coated with ITO and contact metal are widely available. The contact metal over the ITO helps provide reduced resistance pathways where the anode connections do not need to be transparent, in particular for external contacts to the device. The contact metal is removed from the ITO where it is not wanted, in particular where it would otherwise obscure the display, by a standard process of photolithography followed by etching.

A substantially transparent hole injection layer 106 is deposited over the anode layer, followed by an electroluminescent layer 108, and a cathode 110. The electroluminescent layer 108 may comprise, for example, a PPV (poly(p-phenylenevinylene)) and the hole injection layer 106, which helps match the hole energy levels of the anode layer 104 and electroluminescent layer 108, may comprise a conductive transparent polymer, for example PEDOT:PSS (polystyrene-sulphonate doped polyethylene-dioxythiophene) from H.C. Starck of Germany. In a typical polymer-based device the hole transport layer 106 may comprise around 200 nm of PEDOT. The light emitting polymer layer 108 is typically around 70 nm in thickness. These organic layers may be deposited by spin coating (afterwards removing material from unwanted areas by plasma etching or laser ablation) or by inkjet printing. In this latter case, banks 112 may be formed on the substrate, for example using photoresist, to define wells into which the organic layers may be deposited. Such wells define light emitting areas or pixels of the display.

Cathode layer 110 typically comprises a low work function metal such as calcium or barium (for example deposited by physical vapour deposition) covered with a thicker, capping layer of aluminium. Optionally an additional layer may be provided immediately adjacent the electroluminescent layer, such as a layer of lithium fluoride, for improved electron energy level matching. Mutual electrical isolation of cathode lines may be achieved or enhanced through the use of cathode separators (not shown in FIG. 5).

The same basic structure may also be employed for small molecule devices.

Typically a number of displays are fabricated on a single substrate and at the end of the fabrication process the substrate is scribed, and the displays separated before an encapsulating can is attached to each to inhibit oxidation and moisture ingress. Alternatively, the displays can be encapsulated prior to scribing and separating.

To illuminate the OLED, power is applied between the anode and cathode by, for example, battery 118 illustrated in FIG. 5. In the example shown in FIG. 5 light is emitted through transparent anode 104 and substrate 102 and the cathode is generally reflective. Such devices are referred to as “bottom emitters”. Devices which emit through the cathode (“top emitters”) may also be constructed, for example, by keeping the thickness of cathode layer 110 less than around 50-100 nm so that the cathode is substantially transparent and/or using a transparent cathode material such as ITO.

Referring now to FIG. 5b, this shows a simplified cross-section through a passive matrix OLED display device 150, in which like elements to those of FIG. 5 are indicated by like reference numerals. As shown, the hole transport layer 106 and the electroluminescent layer 108 are subdivided into a plurality of pixels 152 at the intersection of mutually perpendicular anode and cathode lines defined in the anode metal 104 and cathode layer 110 respectively. In the figure conductive lines 154 defined in the cathode layer 110 run into the page and a cross-section through one of a plurality of anode lines 158 running at right angles to the cathode lines is shown. An electroluminescent pixel 152 at the intersection of a cathode and anode line may be addressed by applying a voltage between the relevant lines. The anode metal layer 104 provides external contacts to the display 150 and may be used for both anode and cathode connections to the OLEDs (by running the cathode layer pattern over anode metal lead-outs).

The above mentioned OLED materials, and in particular the light emitting polymer material and the cathode, are susceptible to oxidation and to moisture. The device is therefore encapsulated in a metal or glass can 111, attached by UV-curable epoxy glue 113 onto anode metal layer 104. Preferably the anode metal contacts are thinned where they pass under the lip of the metal can 111 to facilitate exposure of glue 113 to UV light for curing.

Considerable effort has been dedicated to the realization of a full-colour, all plastic screen. The major challenges to achieving this goal have been: (1) access to conjugated polymers emitting light of the three basic colours red, green and blue; and (2) the conjugated polymers must be easy to process and fabricate into full-colour display structures. Polymer light emitting devices (PLEDs) show great promise in meeting the first requirement, since manipulation of the emission colour can be achieved by changing the chemical structure of the conjugated polymers. However, while modulation of the chemical nature of conjugated polymers is often easy and inexpensive on the lab scale it can be an expensive and complicated process on the industrial scale. The second requirement of easy processability and build-up of full-colour matrix devices raises the question of how to micro-pattern fine multicolour pixels and how to achieve full-colour emission. In order to contribute to the development of a full-colour display, conjugated polymers exhibiting direct colour-tuning, good processability and the potential for inexpensive large-scale fabrication have been sought. Inkjet printing and hybrid inkjet printing technology have attracted much interest for the patterning of PLED devices (see, for example, Science 1998, 279, 1135; Wudl et al, Appl Phys. Lett. 1998, 73, 2561; and J. Bharathan, Y. Yang, Appl. Phys. Lett. 1998, 72, 2660).

Active matrix organic light-emitting devices (AMOLEDs) are known in the art wherein electroluminescent pixels and a cathode are deposited onto a glass substrate comprising active matrix circuitry for controlling individual pixels and a transparent anode. Light in these devices may be emitted towards the viewer through the anode and the glass substrate (so-called bottom-emission) or through a transparent cathode (so-called “top-emitting” devices).

An Example of a top-emitting device is shown in FIG. 6. The top-emitting device comprises a substrate 202 on which an insulating planarization layer 204 is disposed. A via hole is provided in the planarization layer 204 so an anode can be connected to its associated TFT (not shown). An anode 206 is disposed on the planarization layer 204 over which well-defining banks 208 are provided. The anode 206 is preferably reflective. Electroluminescent material 210 is disposed in the wells defined by the banks and a transparent cathode 212 is deposited over the wells and the banks to form a continuous layer.

Inkjet printing of electroluminescent formulations is a cheap and effective method of forming patterned devices. As disclosed in EP-A-0880303, this entails use of photolithography to form banks having wells therein that define pixels into which the electroluminescent material is deposited by inkjet printing. Various structures for the well-defining banks have been proposed.

WO 2005/076386 discloses undercut well-defining banks formed from a single layer of resist. It has been found that undercut banks can be useful in improving containment of material deposited from solution into the wells. Furthermore, the undercut banks improve the uniformity of the film of material formed when the solution dries. However, a problem with such undercut banks is that it is often desired to form a continuous layer of material such as an electrode layer over the tops of the wells. The undercut structure of the banks can cause breakages in such an overlying layer around the edges of the wells leading to shorting problems.

WO 2007/023272 discloses a well defined by an organic bank layer disposed over an inorganic dielectric spacer layer wherein the organic bank layer overhangs the inorganic dielectric spacer layer to form an overhanging step structure around the edge of the well as shown in FIG. 5 of WO 2007/023272. This structure is formed in a two step process by first patterning the organic bank layer (by exposing to UV, developing, and rinsing) and then etching away the inorganic dielectric material from the base of the well (using a suitable etchant for the inorganic dielectric material) until the overhanging step structure is formed at the sides of the well. It is described that the organic bank provides an etch mask for the second step of etching the inorganic dielectric material. According to an alternative embodiment shown in FIGS. 17a to 17c of WO 2007/023272, instead of forming an overhanging or negative step structure, a positive step structure can be formed around the edges of the well in a three step process by first patterning the bank layer, then etching away the inorganic dielectric material from the base of the well, and finally removing further material from the edge of the bank layer around the periphery of the well to expose the edge of the underlying inorganic dielectric layer such that the inorganic dielectric layer and the bank layer form a positive step structure with the edge of the bank layer set back from the edge of the inorganic dielectric layer. The upper bank layer in the aforementioned embodiments of WO 2007/023272 has a positive profile such that a continuous layer of material such as an electrode layer can be deposited over the tops of the wells without breakages occurring around the edges of the wells. However, the multi-step processes described for manufacturing these bank structures increases manufacturing time and complexity thus increasing cost.

It is an aim of the present invention to improve on the devices and methods of manufacture described above.

### SUMMARY OF THE PRESENT INVENTION

According to a first aspect of the present invention there is provided a method of manufacturing an electronic device, the method comprising: providing a base comprising circuit elements; forming a double bank well-defining structure over the base, the double bank well-defining structure comprising a first layer of insulating material and a second layer of insulating material thereover; and depositing a solution of organic material in a well defined by the double bank well-defining structure, wherein the double bank well-defining structure is formed by removing material from the first and second layers in a single processing step to form the well, and wherein the first and second layers are made of materials having different removal rates for the single processing step whereby a step structure is formed around a periphery of the well due to the difference in removal rates of the materials of the first and second layers.

The present applicant has realized that while double bank step structures can be advantageous for containment of organic material deposited from solution, the multiple steps required to form such structures can increase manufacturing time and complexity thus increasing cost. For example, in the prior art previously discussed, double bank step structures are formed in at least a two step process whereby the material of the first and second layers is removed in separate processing steps. It is also disclosed in the prior art that a third step may be used to remove further material from the upper layer of the double bank structure in order to form a positive step structure with the edges of the lower layer exposed.

After identifying this problem, the present applicant has realized that by selecting suitable materials for the two bank layers, and by selecting a suitable removal technique for the two layers, a double bank well-defining structure can be formed by removing material from the first and second layers in a single processing step whereby a step structure is formed due to a difference in removal rate of the material of the first and second layers. Accordingly, a double bank step structure can be formed while avoiding multiple processing steps thus reducing manufacturing time, complexity and cost.

This contrasts with prior art arrangements such as those described in WO 2007/023272 in which the organic bank layer and the inorganic spacer layer require different processing steps for their removal when forming a well. The organic layer is removed by exposing to UV and then developing. This process does not remove the inorganic material of the underlying layer. The inorganic material is removed using an inorganic etchant which does not remove any of the overlying organic layer which is described as acting as an etch mask. In this sense, the materials of the bank and spacer layers in WO 2007/023272 are orthogonal which is completely contrary to the present invention.

In accordance with one embodiment of the present invention, if the first layer of bank material is removed at a faster rate than the second bank layer then an overhanging or negative step structure can be formed in which the second layer protrudes out over the edge of the first layer. Alternatively, if the first layer of bank material is removed at a slower rate than the second bank layer then a positive step structure can be formed in which the with the edge of the second layer is set back from the edge of the first layer.

The applicant has identified a number of possible materials and techniques for achieving the present invention. The materials of the first and second layers may be inorganic or organic. The material in one of the layers may comprise a cross-linked matrix and the material in the other of the layers may have no cross-linking. The cross-linking increases resistance to removal such that the layer having no cross-linking will be removed more quickly than the layer comprising cross-linking. Alternatively, both layers may comprise cross-linking which the amount of cross-linking made different in each layer. The layer having a lower degree of cross-linking is more readily removed and the amount of cross-linking in each layer can be tuned to achieve a desired size of step structure. For example, a large difference in the amount of cross-linking in each layer results in a larger step structure whereas a smaller difference in the amount of cross-linking in each layer results in a smaller step structure. The amount of cross-linking can be controlled by tuning the number of cross-linkable groups in the materials and/or controlling cross-linking conditions such as the amount of heat and/or the amount of exposure to UV light.

As an alternative to using different amounts of cross-linking, two different materials may be selected for the bank layers which have an inherently different susceptibility to the processing step for removing the layers of material when forming the double bank structure. For example, some organic materials are softer and more readily removed than other organic materials.

The materials used for the two bank layers may be polymers. The polymers may be cross-linked and/or comprise different repeat units such that they have an inherently different susceptibility to the processing step for removing the layers of material when forming the double bank structure as described above. Alternatively, or additionally, the polymers used for the two bank layers may have a different degree of polymerisation. Generally, polymers having a low degree of polymerization will be more readily removed when compared to polymers having a higher degree of polymerization.

The step of forming the double bank well-defining structure may comprise: depositing the first layer of insulating material over the base; baking the first layer of insulating material; depositing the second layer of insulating material thereover; and baking the second layer prior to removing material from the first and second layers in order to define a well. The baking steps are provided to make the layers more robust and remove any solvent if the layers are deposited from solution. This technique can also be used in the method of the present invention. However, the applicant has realized that when baking the second layer, the first layer will inevitable be exposed to further baking. As such, the first layer is exposed to a longer baking time than the second layer and this can increase its resistance to the removal step relative to the second layer. While this is not a problem for embodiments in which a positive step is desired for the double bank structure, it can be a problem when forming an overhanging structure. This extra heating of the first layer can be compensated for by selecting a material for the first layer which is still more readily removable than the material of the second layer, even after additional baking. Alternatively, the first baking step may be reduced in time and/or temperature or removed all together. The second baking step may alternatively or additionally be increased in time or temperature such that the relative contribution of the first bake (if present) to the robustness of the first layer is reduced.

According to certain embodiments, the temperature for the first bake may be in the range 80° to 180°, more preferably 100° to 160°, more preferably still 120° to 140°, and most preferably approximately 130°. The time for the first bake may be in the range 200 to 400 seconds, more preferably 250 to 350 seconds, more preferably still 280 to 320 seconds, and most preferably approximately 300 seconds.

According to certain embodiments, the temperature for the second bake may be in the range 60° to 160°, more preferably 80° to 140°, more preferably still 100° to 120°, and most preferably approximately 115°. The time for the second bake may be in the range 250 to 450 seconds, more preferably 300 to 400 seconds, more preferably still 340 to 380 seconds, and most preferably approximately 360 seconds.

After removing material from the first and second layers in order to define a well a third baking step may be provided. This final bake step will usually be longer than either of the first and second bake steps and may be similar in length to the sum of the first and second bake steps. The temperature of the third bake step may be the same or similar to the second bake step. According to certain embodiments, the temperature for the third bake may be in the range 60° to 160°, more preferably 80° to 140°, more preferably still 100° to 120°, and most preferably approximately 115°. The time for the third bake may be in the range 400 to 800 seconds, more preferably 500 to 700 seconds, more preferably still 550 to 650 seconds, and most preferably approximately 600 seconds.

Various techniques for the single removal step may be utilized according to different embodiments of the present invention. For example, a photo patternable material such as a positive photo resist can be used for the second layer and then exposed to UV light in order to pattern the layer. A developer can then be used to remove exposed portions of the second layer and underlying regions of the first layer. If the material of the first layer is selected to be removable by the developer at a faster rate than the UV exposed material of the second layer then an overhanging structure can be formed. The develop time may be increased to allow sufficient time to form the overhanging structure.

According to certain embodiments, the develop time may be in the range 40 to 120 seconds, more preferably 60 to 100 seconds, more preferably still 70 to 90 seconds. The developer may be deposited by, for example, spraying. The rate of deposition of the developer may be in the range 300 to 1000 ml per minute, more preferably 400 to 900 ml per minute, more preferably still 500 to 800 ml per minute. The rate of deposition of the developer may be varied during deposition. In particular, the rate used for removing the top bank layer may be different to the rate used for removing the lower bank layer. For example, the developer may be deposited at a lower rate initially when removing the top bank layer and then a higher rate for removing the lower bank layer. The initial lower rate may be provided for a longer time than the later higher rate deposition. For example, a rate of 450 to 550 ml per minute may be applied initially for a period of 50 to 70 seconds and then a rate of 700 to 800 ml per minute may be applied for a further period of 15 to 30 seconds.

If the material of the first layer is selected to be removable at a slower rate than the UV exposed material of the second layer then a positive step structure can be formed.

As an alternative to the positive photo resist mentioned above, a negative photo resist may be used for the second layer. In this case, after exposure to UV light the developer removes non-exposed portions of the second layer and underlying regions of the first layer.

Alternatively still, the material of the second layer may not be photo patternable. In this case, a patterned mask layer can be formed over the second layer of bank material. Exposed portions of the second layer and underlying regions of the first layer can then be removed by a suitable removing process such as wet etching, dry etching, or dissolution in a suitable solvent. After forming the stepped double bank structure, the mask can be removed.

The edges of the individual layers in the double bank well-defining structure may be vertical or have positive or negative profiles. One particularly preferred arrangement comprises an overhanging second layer which as a positive edge profile. With this arrangement, the overhanging structure provides good film forming properties for organic material deposited into the well from solution. At the same time, the positive edge profile of the second bank layer is advantageous for depositing a subsequent layer(s) thereover to form a continuous layer without any breaks therein at well edges. For example, in active matrix organic light emissive devices a cathode layer is deposited over a matrix of wells and it is desired that the cathode forms a continuous layer. The aforementioned double bank structure is ideal for such an application.

Preferably the second bank layer has lower wettability than the first bank layer. The second layer is formed of an inherently low-wettability (high contact angle) material forming a separate and distinct layer as opposed to a treated surface of the first layer in which the chemical nature of the surface of the first layer is modified. This avoids the requirement for such surface treatments which have various associated problems including instability and damage of underlying circuitry.

The organic material may form the active layer of an OTFT or an active layer of an OLED.

In the case of an OTFT, the circuit elements of the base comprise source and drain electrodes over which the double bank structure is disposed with a channel region defined between the source and drain electrodes. For a bottom-gate OTFT, the base also comprises a gate electrode with a gate dielectric disposed thereover, the source and drain electrodes being disposed over the gate dielectric.

In the case of an OLED, the circuit elements of the base comprise a lower electrode of the OLED. In an active matrix OLED display device, the circuit elements of the base also comprise an OTFT which itself may be formed using a double bank structure in accordance with the present invention.

The organic material may be conductive or semi-conductive and may be deposited in an aqueous solution or alternatively an organic solvent. Inkjet printing is the preferred method for depositing the solution of organic semiconductive material in the wells defined by the double bank well-defining structure. However, using a double bank structure in which the top layer has a very low wettability (a very high contact angle), other solution processing techniques are possible. For example, the solution may be deposited in a less discriminate manner over the substrate, e.g. flood printing, and the very high contact angle top-layer of the bank structure ensures that the solution flows into the wells such that none of the solution remains over the bank structure.

Preferably the first and second layers of the double bank well-defining structure are formed of an organic material, most preferably polymer materials. The present applicant has found that certain fluorinated polymers such as Cytop have a much higher contact angle, and are thus a much lower wettability, than other fluorinated polymers, for example, greater than 80°. The present applicant has found that these very high contact angle polymers have certain disadvantages for use in single layer bank structures such as those described in US 2007/0023837, i.e. they result in films within the wells which are not uniform in thickness as described previously. However, the present applicant has found that they are ideal for use as a top layer in a double bank structure.

Preferably the contact angle of the second layer of insulating material is even higher, e.g. greater than 100°. Examples of very high contact angle materials include Cytop-type materials from Aldrich. An example of a Cytop-type material is Poly-1,1,2,4,4,5,5,6,7,7-decafluoro-3-oxa-1,6-heptadiene which has a contact angle of approximately 135°. This may be provided in amount of 8-10% by weight in a solvent of perfluorotrialkylamine constituting 90-92% by weight of the solution. Such materials have been found to be particularly useful for depositing organic material from aqueous solution, for example, aqueous solutions of conductive polymers, particularly hole injecting polymers such as PEDOT. Such materials are also useful for depositing organic material from organic solvents. As such, a double bank structure comprising a second layer of such a material can be used, for example, when depositing a hole injecting layer from aqueous solution and a light-emissive layer from an organic solvent.

The present applicant has identified that it is particularly advantageous to form the second layer of the double bank structure using a solution comprising a fluorinated polymer and a fluorinated solvent.

Another problem which the present applicant has identified is that of poor adhesion between the two layers of material in the double bank structure. Accordingly, the present applicant has found it beneficial to provide an adhesive layer between the two layers, for example, an adhesive resin. This may be deposited on the first layer of the bank structure, by spin coating for example, prior to deposition of the second layer.

The present applicant has yet further found that baking can decrease the wettability of the second layer of bank material. As such, they have found it beneficial to provide a baking step prior to deposition of organic material from solution. The bake may be at a temperature in the range 150 to 250° C., more preferably, 170 to 210° C., most preferably 180 to 200° C. The bake is preferably performed in an inert atmosphere such as N₂. For an organic light-emissive device, hole injecting material such as PEDOT may be deposited prior to the bake such that the hole injecting layer and the bank structure are baked at the same time prior to deposition of the organic light-emissive material in the wells.

Yet another problem that the present applicant has identified is that after forming the wells in a bank structure, it is desirable to provide a cleaning step such as an O₂ plasma treatment. Such a step cleans the surfaces in the wells and increases wettability of these surfaces prior to deposition or organic material therein. However, the present applicant has found that such a step greatly increases the wettability of surfaces of the bank which have been previously treated with, for example, a fluorine based plasma treatment in order to decrease their wettability. In fact, contact angles of such a treated surface can drop to under 10° after such a cleaning step. As such, when containment of organic material in the wells has been an issue, such a cleaning step had to be avoided. In contrast, the present applicant has found that when using a double bank structure with an inherently low wetting second layer, the cleaning step can be performed while retaining good de-wetting characteristics over the bank. For example, the contact angle for Cytop-type materials remains over 100° even after an O₂ plasma cleaning step.

In one particularly preferred embodiment, the previously described baking step is performed after the cleaning step and prior to depositing the solution of organic material in wells defined by the double bank well-defining structure. The baking step has been found to regenerate a low-wettability surface on the bank after cleaning using, for example, an O₂ plasma.

The overhanging or positive step structures in accordance with embodiments of the present invention can allow the wells to be overfilled with solution. Such structures can also provide two different pinning points for different fluids deposited in the wells, one at an edge of the first layer around the well and one at an edge of the second layer. This can ensure, for example, that on drying a second material deposited in the wells completely covers a first material deposited in the wells, particularly around the edges of the wells. The different fluids may be selected to have different wetting capabilities, for example, one of the fluids may be an aqueous solution and the other of the fluids may comprise an organic solvent.

The double bank well-defining structure may comprise discrete rings which define the perimeter of at least one well without extending to the perimeter of adjacent wells. This so-called “ring bank” arrangement comprises a plurality of discrete rings of bank material and is described in the present applicant's co-pending application PCT/GB2007/003595. This arrangement contrast with a conventional bank structure which is basically a continuous sheet with a plurality of holes (wells) formed therein.

According to a second aspect of the present invention there is provided an electronic device comprising: a base comprising circuit elements; a double bank well-defining structure over the base, the double bank well-defining structure comprising a first layer of insulating material and a second layer of insulating material thereover; and a layer of solution processable organic material in a well defined by the double bank well-defining structure, wherein the first and second layers of insulating material form a step structure around a periphery of the well, wherein the first and second layers are made of materials which are removable by a single common processing step and are adapted to have different removal rates for the single common processing step.

For example, the first and second layers may be both organic or both inorganic such that they are removable by a single common processing step as opposed to being made of orthogonal materials such as the inorganic/organic combination disclosed in WO 2007/023272. The materials are adapted to have different removal rates for the single common processing step by, for example, having different amounts of cross-linking therein. As such, the stepped double bank structure can be formed using the single common processing step. Embodiments of the second aspect may have any of the features discussed previously with respect to the first aspect and have the same associated advantages, i.e. reduced manufacturing time, complexity and cost.

According to preferred embodiments there is provided an organic thin film transistor or an organic light-emissive device manufactured according to the previously described structures and methods. According to certain embodiments there is provided an active matrix organic optical device and method of making the same in which an organic thin film transistor and an organic light-emissive device are provided according to the previously described structures and methods.

According to a third aspect of the present invention there is provided a method of manufacturing an electronic substrate for an electronic device, the method comprising: providing a base comprising circuit elements; and forming a double bank well-defining structure over the base, the double bank well-defining structure defining a well and comprising a first layer of insulating material and a second layer of insulating material, wherein the double bank well-defining structure is formed by removing material from the first and second layers in a single processing step to form the well, and wherein the first and second layers are made of materials having different removal rates for the single processing step whereby a step structure is formed around a periphery of the well due to the difference in removal rates of the materials of the first and second layers.

According to a fourth aspect of the present invention there is provided an electronic substrate for an electronic device, the electronic substrate comprising: a base comprising circuit elements; and a double bank well-defining structure over the base, the double bank well-defining structure defining a well and comprising a first layer of insulating material and a second layer of insulating material thereover, the first and second layers forming a step structure around a periphery of the well, wherein the first and second layers are made of materials which are removable by a single common processing step and are adapted to have different removal rates for the single common processing step.

Electronic substrates according to embodiments of the third and fourth aspects may be manufactured according to the previously described structures and methods depending on required specifications and then packaged and sold to device manufacturers for further processing in order to form electronic devices.

### SUMMARY OF THE DRAWINGS

The present invention will now be described in further detail, by way of example only, with reference to the accompanying drawings in which:

FIG. 1 shows a known top-gate organic thin film transistor arrangement;

FIG. 2 shows a known bottom-gate organic thin film transistor arrangement;

FIG. 3 shows a bottom-gate organic thin film transistor arrangement with a well for containing the organic semiconductor;

FIG. 4 shows a top-gate organic thin film transistor arrangement with a well for containing the organic semiconductor;

FIG. 5 shows a bottom-emitting organic light emitting device according to the prior art;

FIG. 5b shows a bottom-emitting organic light emitting display according to the prior art;

FIG. 6 shows a top-emitting organic light emitting device according to the prior art;

FIG. 7 shows a double bank structure according to an embodiment of the present invention;

FIG. 8 shows the method steps involved in forming a double bank structure according to an embodiment of the present invention;

FIG. 9 shows a double bank structure with a positive step profile which may be formed using the method of the present invention;

FIG. 10 illustrates a portion of an active matrix organic light emitting display comprising an organic thin film transistor and an organic light emitting device; and

FIG. 11 illustrates a portion of another active matrix organic light emitting display arrangement comprising an organic thin film transistor and an organic light emitting device.

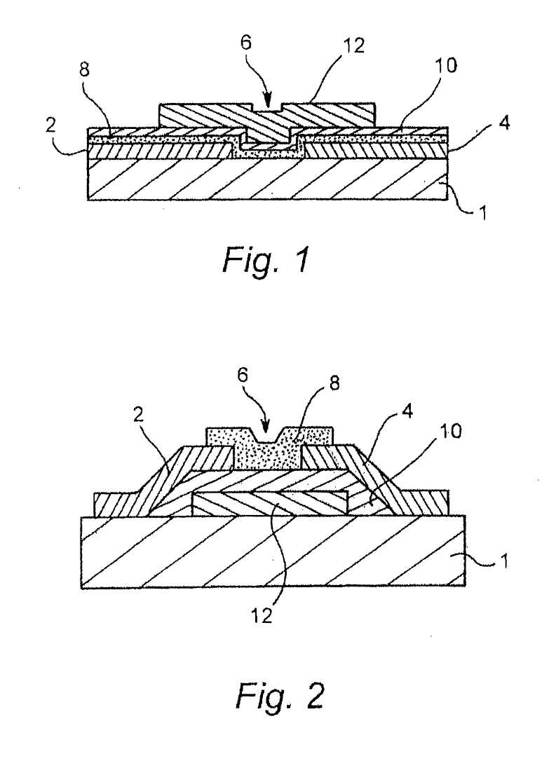

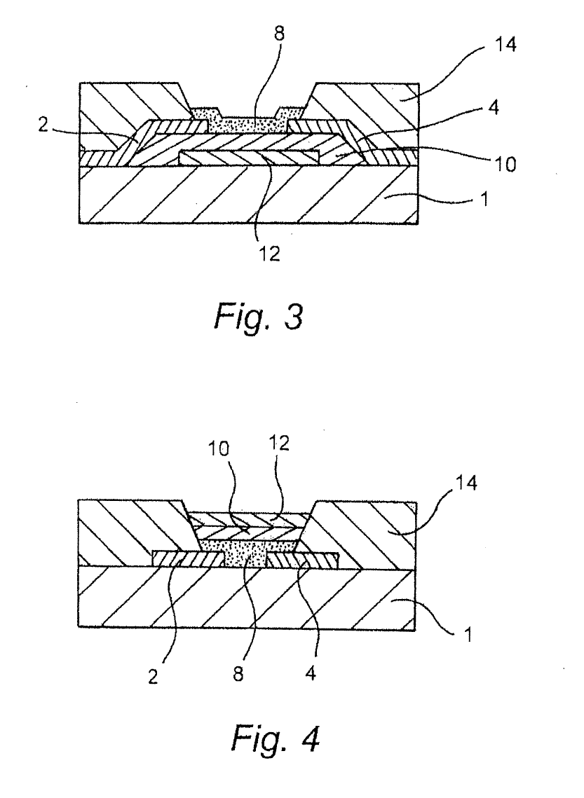

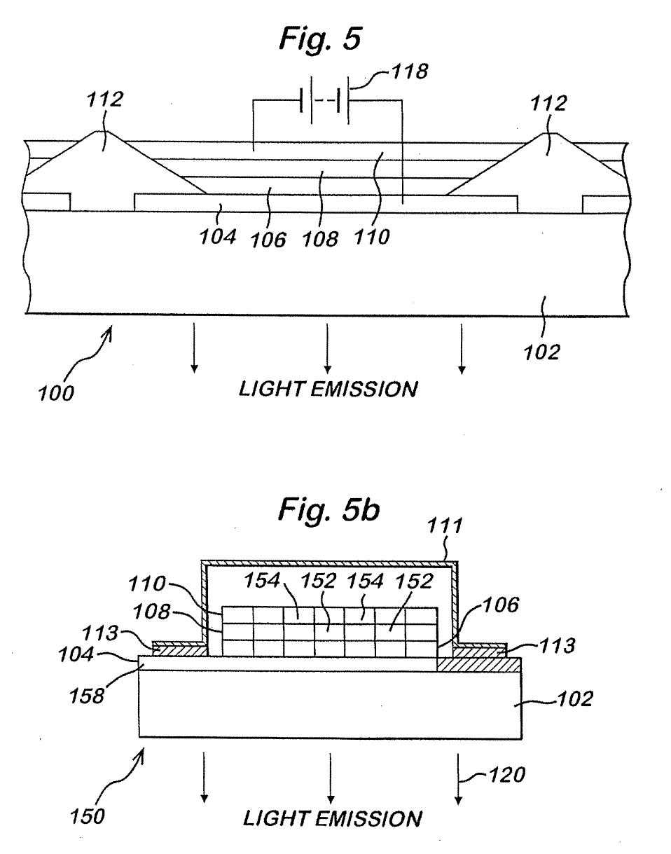

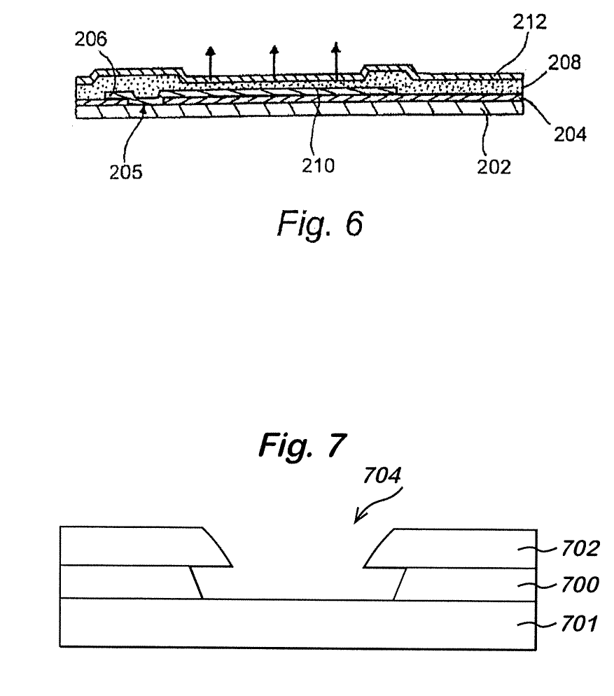

### DETAILED DESCRIPTION OF PREFERRED EMBODIMENTS

Embodiments of the present invention relate to printed electronic devices which comprise a patterned well-defining bank structure and methods of making the same. A double bank well-defining structure is formed by removing material from first and second bank layers in a single processing step whereby a step structure is formed due to a difference in removal rate of the material of the first and second layers.

FIG. 7 shows a double bank structure according to an embodiment of the present invention. The double bank structure is disposed on an electronic substrate 701 and comprises a lower layer 700 and an upper layer 702. The upper layer 702 has a positive profile and also overhangs the lower layer 700.

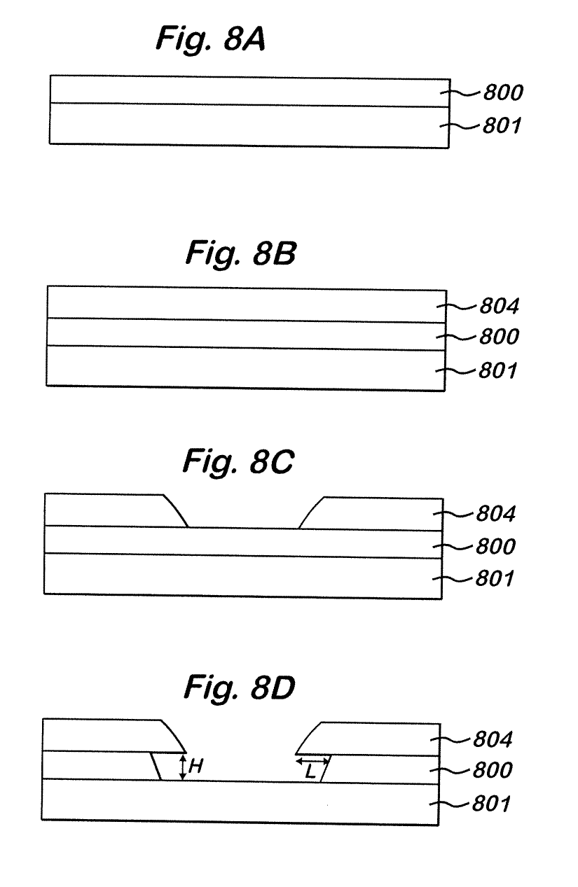

FIG. 8 shows the method steps involved in forming a double bank structure according to the embodiment of FIG. 7. First, a non UV sensitive resist 800 is spin coated on an electronic substrate 801 and soft baked (FIG. 8A). A positive photo resist 804 is then spin coated and soft baked (FIG. 8B). The upper layer is then patterned by exposing to UV light (e.g. at a dose of 100 mJ/cm²) and developed with a developer. This process forms a positive profile for the upper layer 804 (FIG. 8C) and by continuing the developing step the underlying lower layer 800 is removed at a faster rate producing a negative or overhanging step profile for liquid containment (FIG. 8D).

The undercut height H is proportional to the spin speed used to deposit the lower bank layer. The undercut length L can be controlled using an additional bake and development step. By changing the material of the upper bank layer the slope, height, and contact angle of the bank can be changed.

In FIG. 8, both the lower and upper bank layers individually have an edge with a positive angled profile. However, each of these layers may separately have different shapes and angles. For example, the wall of the well defined by the first bank layer 800 may have an undercut edge, a vertical edge, or have an edge with a positive profile. Similarly, the second bank layer 804 may have an undercut edge, a vertical edge, or have an edge with a positive profile.

Examples of suitable materials for the lower bank layer include: Micro chem. LOR A series resist; Micro chem. LOR B series resist; Micro chem. SF lift off resist; and Micro chem. SF slow lift off resist.

Examples of suitable materials for the upper bank layer include: Photo-pattern cytop; Zeon 1168X negative resist; and Shipley 1800 series resists.

The lower bank layer may have a thickness in the range 100 to 300 nm, more preferably 150 to 250 nm, and most preferably approximately 200 nm. The upper bank layer may have a thickness in the range 1 to 3 micrometers.

An example of a suitable developer is Rockwood 238s with a concentration of 2 to 3% TMAH (Tetra-Methyl Ammonium Hydroxide). The develop step may be finished with a distilled water rinse of the substrate.

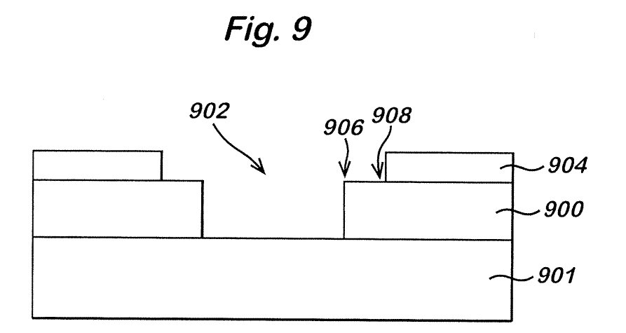

FIG. 9 shows a double bank structure on a substrate 901 according to another embodiment of the present invention comprising a positive step structure around the wells. Such a structure provides two different pinning points for different fluids deposited in the wells, one at an edge 906 of the first layer 900 around the well 902 and one at an edge 908 of the second layer 904 stepped back from the well 902. This can ensure, for example, that on drying a second material deposited in the wells completely covers a first material deposited in the wells, particularly around the edges of the wells. The different fluids may be selected to have different wetting capabilities, for example, one of the fluids may be an aqueous solution and the other of the fluids may comprise and organic solvent. Although the step structure in FIG. 9 is illustrated which vertical walls, different shapes and angles may be provided. For example, the wall of the well defined by the first bank layer 900 may be undercut or have a positive profile. Similarly, the second bank layer 904 may have an undercut edge or have an edge with a positive profile.

Materials and processes suitable for forming an OTFT in accordance with embodiments of the present invention are discussed in further detail below.

### Substrate

The substrate may be rigid or flexible. Rigid substrates may be selected from glass or silicon and flexible substrates may comprise thin glass or plastics such as poly(ethylene-terephthalate) (PET), poly(ethylene-naphthalate) PEN, polycarbonate and polyimide.

### Organic Semiconductor Materials

The organic semiconductive material may be made solution processable through the use of a suitable solvent. Exemplary solvents include: mono- or poly-alkylbenzenes such as toluene and xylene; tetralin; and chloroform. Preferred solution deposition techniques include spin coating and ink jet printing. Other solution deposition techniques include dip-coating, roll printing and screen printing.

Preferred organic semiconductor materials include: small molecules such as optionally substituted pentacene; optionally substituted polymers such as polyarylenes, in particular polyfluorenes and polythiophenes; and oligomers. Blends of materials, including blends of different material types (e.g. a polymer and small molecule blend) may be used.

### Source and Drain Electrodes

For a p-channel OTFT, preferably the source and drain electrodes comprise a high workfunction material, preferably a metal, with a workfunction of greater than 3.5 eV, for example gold, platinum, palladium, molybdenum, tungsten, or chromium. More preferably, the metal has a workfunction in the range of from 4.5 to 5.5 eV. Other suitable compounds, alloys and oxides such as molybdenum trioxide and indium tin oxide may also be used. The source and drain electrodes may be deposited by thermal evaporation and patterned using standard photolithography and lift off techniques as are known in the art.

Alternatively, conductive polymers may be deposited as the source and drain electrodes. An example of such a conductive polymers is poly(ethylene dioxythiophene) (PEDOT) although other conductive polymers are known in the art. Such conductive polymers may be deposited from solution using, for example, spin coating or ink jet printing techniques and other solution deposition techniques discussed above.

For an n-channel OTFT, preferably the source and drain electrodes comprise a material, for example a metal, having a workfunction of less than 3.5 eV such as calcium or barium or a thin layer of metal compound, in particular an oxide or fluoride of an alkali or alkali earth metal for example lithium fluoride, barium fluoride and barium oxide. Alternatively, conductive polymers may be deposited as the source and drain electrodes.

The source and drain electrodes are preferably formed from the same material for ease of manufacture. However, it will be appreciated that the source and drain electrodes may be formed of different materials for optimisation of charge injection and extraction respectively.

The length of the channel defined between the source and drain electrodes may be up to 500 microns, but preferably the length is less than 200 microns, more preferably less than 100 microns, most preferably less than 20 microns.

### Gate Electrode

The gate electrode can be selected from a wide range of conducting materials for example a metal (e.g. gold) or metal compound (e.g. indium tin oxide). Alternatively, conductive polymers may be deposited as the gate electrode. Such conductive polymers may be deposited from solution using, for example, spin coating or ink jet printing techniques and other solution deposition techniques discussed above

Thicknesses of the gate electrode, source and drain electrodes may be in the region of 5-200 nm, although typically 50 nm as measured by Atomic Force Microscopy (AFM), for example.

### Gate Dielectric

The gate dielectric comprises a dielectric material selected from insulating materials having a high resistivity. The dielectric constant, k, of the dielectric is typically around 2-3 although materials with a high value of k are desirable because the capacitance that is achievable for an OTFT is directly proportional to k, and the drain current I_{D} is directly proportional to the capacitance. Thus, in order to achieve high drain currents with low operational voltages, OTFTs with thin dielectric layers in the channel region are preferred.

The dielectric material may be organic or inorganic. Preferred inorganic materials include Si02, SiNx and spin-on-glass (SOG). Preferred organic materials are generally polymers and include insulating polymers such as poly vinylalcohol (PVA), polyvinylpyrrolidine (PVP), acrylates such as polymethylmethacrylate (PMMA) and benzocyclobutanes (BCBs) available from Dow Corning. The insulating layer may be formed from a blend of materials or comprise a multi-layered structure.

The dielectric material may be deposited by thermal evaporation, vacuum processing or lamination techniques as are known in the art. Alternatively, the dielectric material may be deposited from solution using, for example, spin coating or ink jet printing techniques and other solution deposition techniques discussed above.

If the dielectric material is deposited from solution onto the organic semiconductor, it should not result in dissolution of the organic semiconductor. Likewise, the dielectric material should not be dissolved if the organic semiconductor is deposited onto it from solution. Techniques to avoid such dissolution include: use of orthogonal solvents, i.e. use of a solvent for deposition of the uppermost layer that does not dissolve the underlying layer; and crosslinking of the underlying layer.

The thickness of the gate dielectric layer is preferably less than 2 micrometres, more preferably less than 500 nm.

### Further Layers

Other layers may be included in the device architecture. For example, a self assembled monolayer (SAM) may be deposited on the gate, source or drain electrodes, substrate, insulating layer and organic semiconductor material to promote crystallity, reduce contact resistance, repair surface characteristics and promote adhesion where required. In particular, the dielectric surface in the channel region may be provided with a monolayer comprising a binding region and an organic region to improve device performance, e.g. by improving the organic semiconductor's morphology (in particular polymer alignment and crystallinity) and covering charge traps, in particular for a high k dielectric surface. Exemplary materials for such a monolayer include chloro- or alkoxy-silanes with long alkyl chains, e.g. octadecyltrichlorosilane. Similarly, the source and drain electrodes may be provided with a SAM to improve the contact between the organic semiconductor and the electrodes. For example, gold SD electrodes may be provided with a SAM comprising a thiol binding group and a group for improving the contact which may be a group having a high dipole moment; a dopant; or a conjugated moiety.

### OTFT Applications

OTFTs according to embodiments of the present invention have a wide range of possible applications. One such application is to drive pixels in an optical device, preferably an organic optical device. Examples of such optical devices include photoresponsive devices, in particular photodetectors, and light-emissive devices, in particular organic light emitting devices. OTFTs are particularly suited for use with active matrix organic light emitting devices, e.g. for use in display applications.

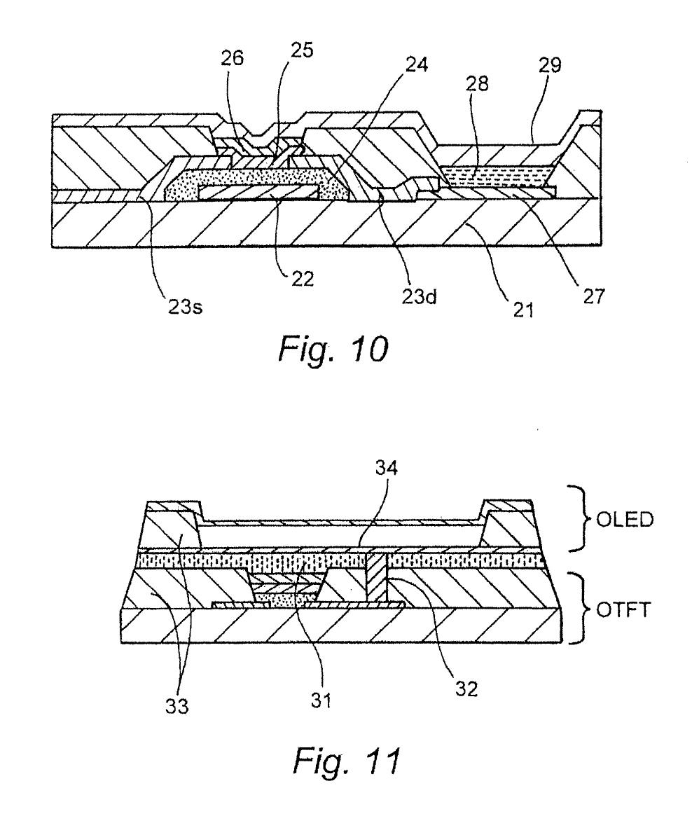

FIG. 10 shows a pixel comprising an organic thin film transistor and an adjacent organic light emitting device fabricated on a common substrate 21. The OTFT comprises gate electrode 22, dielectric layer 24, source and drain electrodes 23s and 23d respectively, and OSC layer 25. The OLED comprises anode 27, cathode 29 and an electroluminescent layer 28 provided between the anode and cathode. Further layers may be located between the anode and cathode, such as charge transporting, charge injecting or charge blocking layers. In the embodiment of FIG. 10, the layer of cathode material extends across both the OTFT and the OLED, and an insulating layer 26 is provided to electrically isolate the cathode layer 29 from the OSC layer 25. In this embodiment, the drain electrode 23d is directly connected to the anode of the organic light emitting device for switching the organic light emitting device between emitting and non-emitting states.

The active areas of the OTFT and the OLED are defined by a common bank material formed by depositing a layer of photoresist on substrate 21 and patterning it to define OTFT and OLED areas on the substrate. In accordance with an embodiment of the present invention the common bank has a two-layer structure as described previously.

In an alternative arrangement illustrated in FIG. 11, an organic thin film transistor may be fabricated in a stacked relationship to an organic light emitting device. In such an embodiment, the organic thin film transistor is built up as described above in either a top or bottom gate configuration. As with the embodiment of FIG. 10, the active areas of the OTFT and OLED are defined by a patterned layer of photoresist 33, however in this stacked arrangement, there are two separate bank structures 33—one for the OLED and one for the OTFT. In accordance with an embodiment of the present invention these two separate bank structures each have a two-layer structure as described previously.

A planarisation layer 31 (also known as a passivation layer) is deposited over the OTFT. Exemplary passivation layers include BCBs and parylenes. An organic light emitting device is fabricated over the passivation layer. The anode 34 of the organic light emitting device is electrically connected to the drain electrode of the organic thin film transistor by a conductive via 32 passing through passivation layer 31 and bank layer 33.

It will be appreciated that pixel circuits comprising an OTFT and an optically active area (e.g. light emitting or light sensing area) may comprise further elements. In particular, the OLED pixel circuits of FIGS. 10 and 11 will typically comprise least one further transistor in addition to the driving transistor shown, and at least one capacitor.

It will be appreciated that the organic light emitting devices described herein may be top or bottom-emitting devices. That is, the devices may emit light through either the anode or cathode side of the device. In a transparent device, both the anode and cathode are transparent. It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium.

Transparent cathodes are particularly advantageous for active matrix devices because emission through a transparent anode in such devices may be at least partially blocked by OTFT drive circuitry located underneath the emissive pixels as can be seen from the embodiment illustrated in FIG. 11.

Materials and processes suitable for forming an OLED in accordance with embodiments of the present invention are discussed in further detail below.

### General Device Architecture

The architecture of an electroluminescent device according to an embodiment of the invention comprises a transparent glass or plastic substrate, an anode and a cathode. An electroluminescent layer is provided between anode and cathode.

In a practical device, at least one of the electrodes is semi-transparent in order that light may be absorbed (in the case of a photoresponsive device) or emitted (in the case of an OLED). Where the anode is transparent, it typically comprises indium tin oxide.

### Charge Transport Layers

Further layers may be located between anode and cathode, such as charge transporting, charge injecting or charge blocking layers.

In particular, it is desirable to provide a conductive hole injection layer, which may be formed from a conductive organic or inorganic material provided between the anode and the electroluminescent layer to assist hole injection from the anode into the layer or layers of semiconducting polymer. Examples of doped organic hole injection materials include doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and poly(thienothiophene). Examples of conductive inorganic materials include transition metal oxides such as VOx MoOx and RuOx as disclosed in Journal of Physics D: Applied Physics (1996), 29(11), 2750-2753.

If present, a hole transporting layer located between anode and electroluminescent layer preferably has a HOMO level of less than or equal to 5.5 eV, more preferably around 4.8-5.5 eV. HOMO levels may be measured by cyclic voltammetry, for example.

If present, an electron transporting layer located between electroluminescent layer and cathode preferably has a LUMO level of around 3-3.5 eV.

### Electroluminescent Layer

The electroluminescent layer may consist of the electroluminescent material alone or may comprise the electroluminescent material in combination with one or more further materials. In particular, the electroluminescent material may be blended with hole and/or electron transporting materials as disclosed in, for example, WO 99/48160, or may comprise a luminescent dopant in a semiconducting host matrix. Alternatively, the electroluminescent material may be covalently bound to a charge transporting material and/or host material.

The electroluminescent layer may be patterned or unpatterned. A device comprising an unpatterned layer may be used an illumination source, for example. A white light emitting device is particularly suitable for this purpose. A device comprising a patterned layer may be, for example, an active matrix display or a passive matrix display. In the case of an active matrix display, a patterned electroluminescent layer is typically used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

Suitable materials for use in electroluminescent layer include small molecule, polymeric and dendrimeric materials, and compositions thereof. Suitable electroluminescent polymers include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein. Suitable electroluminescent dendrimers include electroluminescent metal complexes bearing dendrimeric groups as disclosed in, for example, WO 02/066552.

### Cathode

The cathode is selected from materials that have a workfunction allowing injection of electrons into the electroluminescent layer. Other factors influence the selection of the cathode such as the possibility of adverse interactions between the cathode and the electroluminescent material. The cathode may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode will comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Optical devices tend to be sensitive to moisture and oxygen. Accordingly, the substrate preferably has good barrier properties for prevention of ingress of moisture and oxygen into the device. The substrate is commonly glass. However, alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is preferably encapsulated with an encapsulant to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

### Solution Processing

A single polymer or a plurality of polymers may be deposited from solution. Suitable solvents for polyarylenes, in particular polyfluorenes, include mono- or poly-alkylbenzenes such as toluene and xylene. Particularly preferred solution deposition techniques are spin-coating and inkjet printing.

Spin-coating is particularly suitable for devices wherein patterning of the electroluminescent material is unnecessary—for example for lighting applications or simple monochrome segmented displays.

Inkjet printing is particularly suitable for high information content displays, in particular full colour displays. Inkjet printing of OLEDs is described in, for example, EP 0880303.

Other solution deposition techniques include dip-coating, roll printing and screen printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

### Emission Colours

By “red electroluminescent material” is meant an organic material that by electroluminescence emits radiation having a wavelength in the range of 600-750 nm, preferably 600-700 nm, more preferably 610-650 nm and most preferably having an emission peak around 650-660 nm.

By “green electroluminescent material” is meant an organic material that by electroluminescence emits radiation having a wavelength in the range of 510-580 nm, preferably 510-570 nm.

By “blue electroluminescent material” is meant an organic material that by electroluminescence emits radiation having a wavelength in the range of 400-500 nm, more preferably 430-500 nm.

### Hosts for Phosphorescent Emitters

Numerous hosts are described in the prior art including “small molecule” hosts such as 4,4′-bis(carbazol-9-yl)biphenyl), known as CBP, and (4,4′,4″-tris(carbazol-9-yl)triphenylamine), known as TCTA, disclosed in Ikai et al., Appl. Phys. Lett, 79 no. 2, 2001, 156; and triarylamines such as tris-4-(N-3-methylphenyl-N-phenyl)phenylamine, known as MTDATA. Polymers are also known as hosts, in particular homopolymers such as poly(vinyl carbazole) disclosed in, for example, Appl. Phys. Lett. 2000, 77(15), 2280; polyfluorenes in Synth. Met. 2001, 116, 379, Phys. Rev. B 2001, 63, 235206 and Appl. Phys. Lett. 2003, 82(7), 1006; poly[4-(N-4-vinylbenzyloxyethyl, N-methylamino)-N-(2,5-di-tert-butylphenylnapthalimide] in Adv. Mater. 1999, 11(4), 285; and poly(para-phenylenes) in J. Mater. Chem. 2003, 13, 50-55. Copolymers are also known as hosts.

### Metal Complexes (Mostly Phosphorescent but Includes Fluorescent at the End)

Preferred metal complexes comprise optionally substituted complexes of formula:

ML¹_{q}L²ᵣL³ₛ

wherein M is a metal; each of L¹, L² and L³ is a coordinating group; q is an integer; r and s are each independently 0 or an integer; and the sum of (a. q)+(b. r)+(c.s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet or higher states (phosphorescence). Suitable heavy metals M include:

lanthanide metals such as cerium, samarium, europium, terbium, dysprosium, thulium, erbium and neodymium; and

d-block metals, in particular those in rows 2 and 3 i.e. elements 39 to 48 and 72 to 80, in particular ruthenium, rhodium, palladium, rhenium, osmium, iridium, platinum and gold.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals are particularly suitable for emission from triplet excited states. These metals form organometallic complexes with carbon or nitrogen donors such as porphyrin or bidentate ligands of formula:

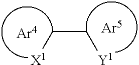

wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

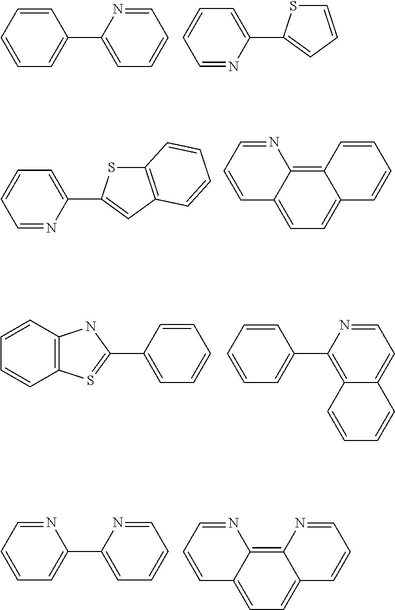

Each of Ar⁴ and Ar⁵ may carry one or more substituents. Two or more of these substituents may be linked to form a ring, for example an aromatic ring. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

A light-emitting dendrimer typically comprises a light-emitting core bound to one or more dendrons, wherein each dendron comprises a branching point and two or more dendritic branches. Preferably, the dendron is at least partially conjugated, and at least one of the core and dendritic branches comprises an aryl or heteroaryl group. In one preferred embodiment, the branch group comprises

Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission colour is determined by the choice of ligand as well as the metal.

The host material and metal complex may be combined in the form of a physical blend. Alternatively, the metal complex may be chemically bound to the host material. In the case of a polymeric host, the metal complex may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

A wide range of fluorescent low molecular weight metal complexes are known and have been demonstrated in organic light emitting devices [see, e.g., Macromol. Sym. 125 (1997) 1-48, U.S. Pat. No. 5,150,006, U.S. Pat. No. 6,083,634 and U.S. Pat. No. 5,432,014]. Suitable ligands for di or trivalent metals include: oxinoids, e.g. with oxygen-nitrogen or oxygen-oxygen donating atoms, generally a ring nitrogen atom with a substituent oxygen atom, or a substituent nitrogen atom or oxygen atom with a substituent oxygen atom such as 8-hydroxyquinolate and hydroxyquinoxalino-10-hydroxybenzo (h) quinolinato (II), benzazoles (III), schiff bases, azoindoles, chromone derivatives, 3-hydroxyflavone, and carboxylic acids such as salicylato amino carboxylates and ester carboxylates. Optional substituents include halogen, alkyl, alkoxy, haloalkyl, cyano, amino, amido, sulfonyl, carbonyl, aryl or heteroaryl on the (hetero) aromatic rings which may modify the emission colour.

While this invention has been particularly shown and described with reference to preferred embodiments thereof, it will be understood by those skilled in the art that various changes in form and detail may be made therein without departing from the scope of the invention as defined by the appended claims.

1. A method of manufacturing an electronic device, the method comprising:
providing a base comprising circuit elements;
forming a double bank well-defining structure over the base, the double bank well-defining structure comprising a first layer of insulating material and a second layer of insulating material thereover; and
depositing a solution of organic material in a well defined by the double bank well-defining structure, wherein the double bank well-defining structure is formed by removing material from the first and second layers in a single processing step to form the well, and wherein the first and second layers are made of materials having different removal rates for the single processing step whereby a step structure is formed around a periphery of the well due to the difference in removal rates of the materials of the first and second layers.

2. A method according to claim 1, wherein the first layer is made of a material which is removed at a faster rate in the single processing step than material of the second layer to form an overhanging step structure in which the second layer protrudes out over an edge of the first layer.

3. A method according to claim 1, wherein the second layer has an edge having a positive profile.

4. A method according to claim 1, wherein the first and second layers comprise organic material.

5. A method according to claim 1, wherein the second layer is cross-linked and the first layer has no cross-linking or is cross-linked to a lesser extent than the second layer.

6. A method according to claim 1, wherein the second layer is made of a material which is harder than the first layer.

7. A method according to claim 1, wherein the first and second layers are made of polymer material.

8. A method according to claim 7, wherein the degree of polymerization in the first layer is lower than the degree of polymerization in the second layer.

9. A method according to claim 1, wherein forming the double bank well-defining structure comprises:
depositing the first layer of insulating material over the electronic substrate;
depositing the second layer of insulating material thereover;
photo patterning the second layer; and
developing the second layer and the first layer in a single developing step.

10. A method according to claim 1, wherein the material of the second layer has a lower wettability than the material of the first layer.

11. A method according to claim 1, wherein the method further comprises depositing a continuous electrode layer over the organic material in the well and the double bank well-defining structure.

12. An electronic device comprising:
a base comprising circuit elements;
a double bank well-defining structure over the base, the double bank well-defining structure comprising a first layer of insulating material and a second layer of insulating material thereover; and
a layer of solution processable organic material in a well defined by the double bank well-defining structure, wherein the first and second layers of insulating material form a step structure around a periphery of the well, wherein the first and second layers are made of materials which are removable by a single common processing step and are adapted to have different removal rates for the single common processing step.

13. A method of manufacturing an electronic substrate for an electronic device, the method comprising:
providing a base comprising circuit elements; and
forming a double bank well-defining structure over the base, the double bank well-defining structure defining a well and comprising a first layer of insulating material and a second layer of insulating material, wherein the double bank well-defining structure is formed by removing material from the first and second layers in a single processing step to form the well, and wherein the first and second layers are made of materials having different removal rates for the single processing step whereby a step structure is formed around a periphery of the well due to the difference in removal rates of the materials of the first and second layers.

14. An electronic substrate for an electronic device, the electronic substrate comprising:
a base comprising circuit elements; and
a double bank well-defining structure over the base, the double bank well-defining structure defining a well and comprising a first layer of insulating material and a second layer of insulating material thereover, the first and second layers forming a step structure around a periphery of the well, wherein the first and second layers are made of materials which are removable by a single common processing step and are adapted to have different removal rates for the single common processing step.
